(19) United States
(12) Patent Application Publication
(10) Pub. No.: US 2011/0061729 A1
(43) Pub. Date: Mar. 17, 2011

(54) Solar Cell and Method of Manufacturing the Same

(75) Inventors: Hyun Woo Lee, Seoul (KR); Eun Joo Lee, Seongnam-si (KR); Hae Seok Lee, Yongin-si (KR); Jun Young Choi, Siheung-si (KR); Dong Joon Oh, Busan (KR); Ji Myung Shim, Incheon (KR); Kyeong Yeon Cho, Yongin-si (KR); Ji Sun Kim, Seoul (KR)

(73) Assignee: SHIN SUNG HOLDINGS CO., LTD., Seongnam-si (KR)

(21) Appl. No.: 12/883,812

(22) Filed: Sep. 16, 2010

(30) Foreign Application Priority Data
Sep. 16, 2009 (KR) 10-2009-0087477

(51) Int. Cl. H01L 31/0216; H01L 31/18

(52) U.S. Cl. 136/256; 438/72; 257/E31.119

(57) ABSTRACT

Provided are a solar cell and a method of manufacturing the same. The method includes implanting impurities of a second conductivity type opposite to a first conductivity type on the entire surface of a semiconductor substrate of the first conductivity type to form an emitter layer, forming a first anti-reflective coating (ARC) layer on the emitter layer, patterning a portion of the first anti-reflective coating (ARC) layer where a front electrode will be formed, forming a second anti-reflective coating (ARC) layer on the first anti-reflective coating (ARC) layer and the emitter layer, and forming the front electrode and a rear electrode on front and rear surfaces of the semiconductor substrate. In this method, a double structure of two anti-reflective coating (ARC) layers with different thicknesses may be formed to make electrode patterns distinct, thereby facilitating alignment of electrodes.

### CROSS-REFERENCE TO RELATED APPLICATION

This application claims priority to and the benefit of Korean Patent Application No. 10-2009-0087477, filed on Sep. 16, 2009 the disclosure of which is incorporated herein by reference in its entirety.

### BACKGROUND

1. Field of the Invention

The present invention relates to a solar cell and a method of manufacturing the same, and more particularly, to a solar cell and a method of manufacturing the same, which makes patterns of front electrodes distinct during formation of an anti-reflective coating (ARC) layer on the surface of the solar cell.

2. Discussion of Related Art

In recent years, with prediction of exhaustion of existing energy sources such as oil and coal, more attention is being paid to exploitation of alternative energy sources. Among the alternative energy sources, solar cells are being significantly considered because the solar cells may utilize abundant solar energy and be free from environmental pollution. Solar cells may be classified into solar heat cells configured to generate steam required for rotating a turbine using solar light and solar light cells configured to convert photons into electric energy using the properties of semiconductor materials. Typically, solar cells may refer to solar light cells (hereinafter, ‘solar cells’).

FIG. 1 is a schematic diagram of a basic structure of a solar cell.

Referring to FIG. 1, the solar cell may have a junction structure between a p-type semiconductor layer 101 and an n-type semiconductor layer 102 like a diode. When light is incident to the solar cell, negative (−) charges (or electrons) and positive (+) charges (or holes) may be generated and moved due to interaction between the light and materials constituting the semiconductor layers 101 and 102, thereby causing the flow of current. The above-described phenomenon may be referred to as a photovoltaic effect. Due to the photovoltaic effect, electrons of the p-type and n-type semiconductor layers 101 and 102 may be attracted toward the n-type semiconductor layer 102, while holes thereof may be attracted toward the p-type semiconductor layer 101. As a result, the electrons and the holes may move to electrodes 103 and 104 bonded to the n-type and p-type semiconductor layers 101 and 102, respectively. By connecting the electrodes 103 and 104 using electric wires, the flow of electricity may be enabled to generate electric power.

To increase the efficiency of the solar cell, maximizing the number of photons reaching an active layer of the solar cell and minimizing loss caused by light reflected by the surface of the solar cell may be very important.

For example, a silicon (Si) layer may be subject to a texturing process so that the reflectance of light incident to a front surface of the solar cell can be reduced and the length of light passing through the solar cell can be increased to facilitate absorption of light in the solar cell. In another case, an anti-reflective coating (ARC) layer may be formed on a substrate to reduce the reflectance of light.

Conventionally, a polished surface of the substrate may reflect about 30 to 50% of incident sunlight, while a pyramidally textured surface of the substrate may reflect about 10 to 20% of incident sunlight, thereby markedly reducing the reflectance of sunlight. Also, it is known that deposition of an ANTI-REFLECTIVE COATING (ARC) layer may lead to reduction of the reflectance of light to about 5 to 10%.

In general, as the number of material layers constituting the ANTI-REFLECTIVE COATING (ARC) layer coated at an appropriate ratio of refractive indices increases, the reflectance of the ANTI-REFLECTIVE COATING (ARC) layer may become lower in a wider wavelength range. However, the ANTI-REFLECTIVE COATING (ARC) layer may mostly include three material layers or less to satisfy both price competitiveness and production yield.

Conventionally, a ZnS/MgF₂ ANTI-REFLECTIVE COATING (ARC) layer has been most widely used. However, since the ZnS/MgF₂ anti-reflective coating (ARC) layer has no surface passivation effect, a commercially available SiNx/SiO₂ anti-reflective coating (ARC) layer is currently being employed.

Meanwhile, to reduce electrical loss of a solar cell, a lightly doped emitter with a high sheet resistance may be applied to the solar cell to reduce surface recombination, and a junction between an electrode and a substrate may be heavily doped to minimize a serial resistance between the electrode and the substrate. The above-described structure may be referred to as a selective emitter structure, which may increase the absorption rate of light energy in a short wavelength range, which corresponds to a blue response range, thereby improving conversion efficiency of the solar cell.

### SUMMARY OF THE INVENTION

According to a conventional method of manufacturing a solar cell having a selective emitter structure, since formation of an anti-reflective coating (ARC) layer is followed by a patterning process, alignment may be precluded during a printing process.

The present invention is directed to a solar cell and a method of manufacturing the same, which may facilitate formation of a front electrode.

Also, the present invention is directed to a solar cell and a method of manufacturing the same, to which a selective emitter is applied to improve surface recombination and a serial resistance of an electrode to increase conversion efficiency

According to an aspect of the present invention, there is provided a method of manufacturing a solar cell. The method includes: implanting impurities of a second conductivity type opposite to a first conductivity type on the entire surface of a semiconductor substrate of the first conductivity type to form an emitter layer; forming a first anti-reflective coating (ARC) layer on the emitter layer; patterning a portion of the first anti-reflective coating (ARC) layer where a front electrode will be formed; forming a second anti-reflective coating (ARC) layer on the first anti-reflective coating (ARC) layer and the emitter layer; and forming the front electrode and a rear electrode on front and rear surfaces of the semiconductor substrate.

After forming the first anti-reflective coating (ARC) layer, the method may further include heavily doping impurities into a portion of the emitter layer where the front electrode will be formed.

The formation of the first anti-reflective coating (ARC) layer may be performed using a thermal growing process. In this case, the thermal growing process may include a wet growing process and a dry growing process.

The formation of the first anti-reflective coating (ARC) layer may be performed at a temperature of about 900° C. using a thermal growing process.

The formation of the first anti-reflective coating (ARC) layer may be performed using a deposition process. The deposition process may be performed using a plasma-enhanced chemical vapor deposition (PECVD) process. A deposition gas used for the deposition process may contain SiH₄.

The first anti-reflective coating (ARC) layer may include SiO₂.

The patterning of the portion of the first anti-reflective coating (ARC) layer where the front electrode will be formed may be performed using an etching process. An etchant used for the etching process may contain an organic polymer.

The formation of the second anti-reflective coating (ARC) layer may be performed using a thermal growing process.

The formation of the second anti-reflective coating (ARC) layer may be performed using a deposition process. In this case, the deposition process may be performed using a PECVD process. A deposition gas used for the deposition process may contain SiH₄.

The second anti-reflective coating (ARC) layer may include SiNₓ.

The first anti-reflective coating (ARC) layer may be formed to have a refractive index of about 1.5 to 2.0. The second anti-reflective coating (ARC) layer may be formed to have a refractive index of about 2.0 to 2.3.

The formation of the electrodes on the front and rear surfaces of the semiconductor substrate may be performed using a printing process.

The rear electrode formed on the rear surface of the semiconductor substrate may include aluminum (Al).

The formation of the rear electrode of the semiconductor substrate may include: coating an Al layer on the rear surface of the semiconductor substrate; and annealing the Al layer to form a back-surface-field (BSF) layer.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a schematic diagram of a basic structure of a solar cell;

FIGS. 2 and 3 are cross-sectional views illustrating a method of manufacturing a solar cell according to an exemplary embodiment of the present invention; and

FIG. 4 is a top view of the solar cell of FIG. 3.

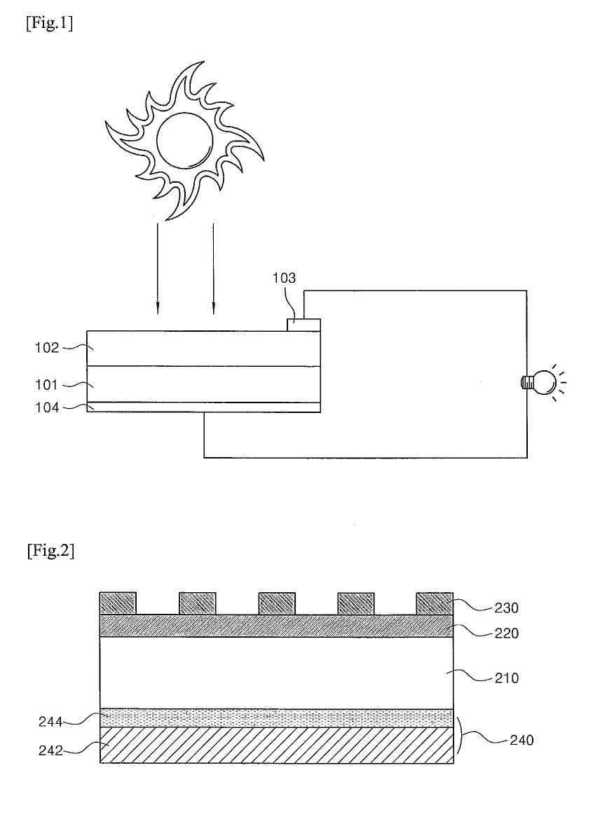

### DETAILED DESCRIPTION OF EXEMPLARY EMBODIMENTS

Exemplary embodiments of the present invention will be described in detail below with reference to the accompanying drawings. To facilitate understanding, identical reference numerals are used, where possible, to designate identical elements that are common to the figures. Descriptions of well-known components and processing techniques are omitted so as not to unnecessarily obscure the embodiments of the present invention. The present invention will now be described more fully with reference to the accompanying drawings, in which exemplary embodiments of the invention are shown.

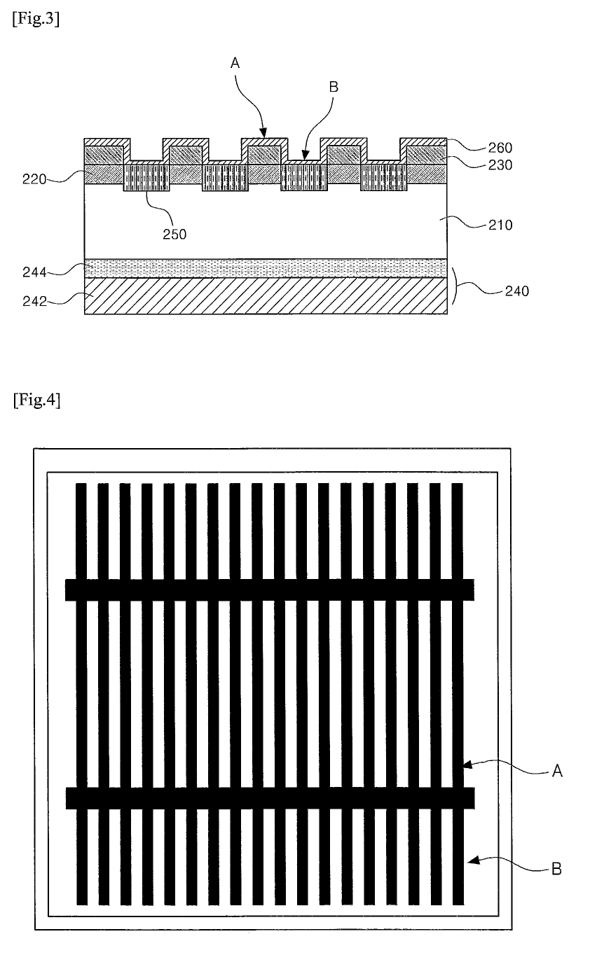

FIGS. 2 and 3 are cross-sectional views illustrating a process of manufacturing a solar cell according to an exemplary embodiment of the present invention.

Referring to FIG. 2, impurities of a second conductivity type may be implanted into the entire surface of a semiconductor substrate 210 of a first conductivity type opposite to the second conductivity type, thereby forming an emitter layer 220. According to an exemplary embodiment of the present invention, the semiconductor substrate 210 may be foamed of p-type crystalline silicon (Si), and the formation of the emitter layer 220 may include lightly doping phosphorus (P) ions into the semiconductor substrate 210.

A first anti-reflective coating (ARC) layer 230 may be formed on the emitter layer 220. According to an exemplary embodiment of the present invention, the first anti-reflective coating (ARC) layer 230 may include SiO₂.

In an exemplary embodiment of the present invention, the formation of the first anti-reflective coating (ARC) layer 230 may be performed using a thermal growing process. In the present invention, the first anti-reflective coating (ARC) layer 230 may be formed at a temperature of about 900° C. or lower using a thermal growing process including both a wet growing process and a dry growing process.

According to another exemplary embodiment of the present invention, the first anti-reflective coating (ARC) layer 230 may be formed using a deposition process. In the present invention, the deposition process may be performed using a plasma-enhanced chemical vapor deposition (PECVD) process. In this case, a deposition gas used for the deposition process may contain SiH₄.

Next, a portion of the first anti-reflective coating (ARC) layer 230 where a front electrode will be formed may be patterned. In the present invention, the patterning of the portion of the first anti-reflective coating (ARC) layer 230 where the front electrode will be formed may be performed using an etching process. FIG. 2 illustrates the patterned first anti-reflective coating (ARC) layer 230. In this case, an etchant used for the etching process may contain an organic polymer.

In the present invention, the first anti-reflective coating (ARC) layer 230 may have a refractive index of about 1.5 to 2.0.

Thereafter, impurities may be heavily doped into a portion of the emitter layer 220 where the front electrode will be formed, thereby forming a heavily doped region 250. As a result, a selective emitter structure may be formed so that a sheet resistance of an emitter can be increased to reduce recombination and a junction between the front electrode and the substrate 210 can be heavily doped to minimize a serial resistance between the front electrode and the substrate 210.

Referring to FIG. 3, a second anti-reflective coating (ARC) layer 260 may be formed on the first anti-reflective coating (ARC) layer 230 and the emitter layer 220. According to an exemplary embodiment of the present invention, the second anti-reflective coating (ARC) layer 260 may include SiNₓ. In the present invention, the second anti-reflective coating (ARC) layer 260 may be formed to have a refractive index of about 2.0 to 2.3.

According to an exemplary embodiment of the present invention, the second anti-reflective coating (ARC) layer 260 may be formed using a thermal growing process.

According to another exemplary embodiment of the present invention, the second anti-reflective coating (ARC) layer 260 may be formed using a deposition process. In this case, the deposition process may be performed using a PECVD process. A deposition gas used for the deposition process may contain SiH₄.

Subsequently, electrodes (not shown) may be formed on front and rear surfaces of the semiconductor substrate 210, thereby completing the manufacture of the solar cell.

In an exemplary embodiment of the present invention, front and rear electrodes may be formed on the front and rear surfaces of the semiconductor substrate 210 using a printing process.

In the present invention, a silver (Ag) electrode may be used as the front electrode because the silver electrode is highly electrically conductive.

In the present invention, an aluminum (Al) electrode, which is highly conductive, may be used as the rear electrode of the semiconductor substrate 210. The Al electrode may have a good affinity for Si and be easily bonded to Si. Also, since Al of the Al electrode is a Group IIIA element, a p⁺ layer (i.e., a back-surface-field (BSF) layer) may be formed between the Al electrode and the semiconductor substrate 210 so that carriers cannot be lost but collected on the surface of the Al electrode to increase the efficiency of the solar cell.

A method of forming the front electrode according to the present invention will now be described in detail. An Al layer 242 may be formed by coating Al on the rear surface of the Al layer 210 and annealed, thereby forming a BSF layer 244. Thus, an electric field may be generated on the rear surface of the substrate 210, thereby reducing recombination on the rear surface of the substrate 210.

In the present invention, the front and rear electrodes may be formed in reverse order.

FIG. 4 is a top view of the solar cell shown in FIG. 3.

Referring to FIG. 4, a dark portion A is where both the first anti-reflective coating (ARC) layer 230 and the second anti-reflective coating (ARC) layer 260 are formed, while a bright portion B is where only the second anti-reflective coating (ARC) layer 260 is formed. In the present invention, since there is a color difference between the portions A and B where electrodes will be formed, alignment may be facilitated, thereby making formation of the electrodes easier and simpler.

According to the present invention, a double structure of two anti-reflective coating (ARC) layers with different thicknesses may be formed to make electrode patterns distinct, thereby facilitating alignment of electrodes. Thus, the manufacture of solar cells may be comparatively simple and economical so that the solar cells can be closer to commercialization and mass production.

Furthermore, according to the present invention, solar cells may be manufactured using a selective emitter process, thereby enhancing a surface reflectance of light and absorptivity of light energy in a short wavelength range.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A method of manufacturing a solar cell, comprising:
forming an emitter layer by implanting impurities of a second conductivity type opposite to a first conductivity type on the entire surface of a semiconductor substrate of the first conductivity type;
forming a first anti-reflective coating (ARC) layer on the emitter layer;
patterning a portion of the first anti-reflective coating (ARC) layer where a front electrode will be formed;
forming a second anti-reflective coating (ARC) layer on the first anti-reflective coating (ARC) layer and the emitter layer; and
forming the front electrode and a rear electrode on front and rear surfaces of the semiconductor substrate.

2. The method of claim 1, further comprising, after forming the first anti-reflective coating (ARC) layer, heavily doping impurities into a portion of the emitter layer where the front electrode will be formed.

3. The method of claim 1, wherein forming the first anti-reflective coating (ARC) layer is performed using a thermal growing process.

4. The method of claim 3, wherein the thermal growing process includes a wet growing process and a dry growing process.

5. The method of claim 3, wherein forming the first anti-reflective coating (ARC) layer is performed at a temperature of about 900° C. using a thermal growing process.

6. The method of claim 1, wherein forming the first anti-reflective coating (ARC) layer is performed using a deposition process.

7. The method of claim 6, wherein the deposition process is performed using a plasma-enhanced chemical vapor deposition (PECVD) process.

8. The method of claim 6, wherein a deposition gas used for the deposition process contains SiH₄.

9. The method of claim 1, wherein the first anti-reflective coating (ARC) layer includes SiO₂.

10. The method of claim 1, wherein patterning the portion of the first anti-reflective coating (ARC) layer where the front electrode will be formed is performed using an etching process.

11. The method of claim 10, wherein an etchant used for the etching process contains an organic polymer.

12. The method of claim 1, wherein forming the second anti-reflective coating (ARC) layer is performed using a thermal growing process.

13. The method of claim 1, wherein forming the second anti-reflective coating (ARC) layer is performed using a deposition process.

14. The method of claim 13, wherein the deposition process is performed using a PECVD process.

15. The method of claim 13, wherein a deposition gas used for the deposition process contains SiH₄.

16. The method of claim 1, wherein the second anti-reflective coating (ARC) layer includes SiNₓ.

17. The method of claim 1, wherein the first anti-reflective coating (ARC) layer is formed to have a refractive index of about 1.5 to 2.0.

18. The method of claim 1, wherein the second anti-reflective coating (ARC) layer is formed to have a refractive index of about 2.0 to 2.3.

19. The method of claim 1, wherein forming the electrodes on the front and rear surfaces of the semiconductor substrate are performed using a printing process.

20. The method of claim 1, wherein the rear electrode formed on the rear surface of the semiconductor substrate includes aluminum (Al).

21. The method of claim 20, wherein forming the rear electrode of the semiconductor substrate comprises:
coating an Al layer on the rear surface of the semiconductor substrate; and
annealing the Al layer to form a back-surface-field (BSF) layer.

22. A solar cell manufactured using the method according to any one of claims 1.
